(19) United States
(12) Patent Application Publication
(10) Pub. No.: US 2017/0290211 A1
(43) Pub. Date: Oct. 5, 2017

(54) BATCH COMPONENT PLACEMENT TEMPLATE

(71) Applicant: INTEL CORPORATION, SANTA CLARA, CA (US)

(72) Inventors: DANIEL CHAVEZ-CLEMENTE, Chandler, AZ (US); XIAO LU, Chandler, AZ (US); JIMIN YAO, Chandler, AZ (US)

(73) Assignee: INTEL CORPORATION, SANTA CLARA, CA (US)

(21) Appl. No.: 15/089,297

(22) Filed: Apr. 1, 2016

(51) Int. Cl. H05K 13/04; H05K 13/02

(52) U.S. Cl. CPC H05K 13/046; H05K 13/029; H05K 13/0404

(57) ABSTRACT

Templates to arrange and/or align components for batch placement on a substrate are described. A batch placement template can include a number of detents physically arranged relative to each other corresponding to a physical arrangement of components to be placed on a substrate. The detents can be sized to allow components to be manipulated into the detents and subsequently picked and placed on the substrate in a batch process.

### TECHNICAL FIELD

Embodiments herein generally relate to electronic assemblies and electronic assembly manufacturing.

### BACKGROUND

Electronic devices can include a number of components (e.g., passive components, active components, or the like) mounted onto a substrate. Often, these components are placed on the substrate during assembly using a pick and place technique. However, as the physical size of the various components decreases and the number of components placed on a substrate increase, misalignment, dropped components, and overall yield loss can result.

### BRIEF DESCRIPTION OF THE DRAWINGS

FIG. 1 illustrates a cut-away side view of a first embodiment of a batch placement template.

FIG. 2 illustrates a top view of the first embodiment of the batch placement template.

FIG. 3 illustrates a perspective view of a first embodiment of a detent of a batch placement template.

FIG. 4 illustrates a perspective view of a second embodiment of a detent of a batch placement template.

FIGS. 5A-5C illustrate a first embodiment of a batch placement system.

FIGS. 6A-6C illustrate a second embodiment of a batch placement system.

FIGS. 7A-7B illustrates a perspective view of a second embodiment of a batch placement template.

FIG. 8 illustrates a cut-away side view of a third embodiment of a batch placement template.

FIG. 9 illustrates a top view of the third embodiment of the batch placement template.

FIG. 10 illustrates a third embodiment of a batch placement system.

FIG. 11 illustrates an embodiment of a first technique to place components on a substrate.

FIGS. 12A-12B illustrates an embodiment of a second technique to place components on a substrate.

FIG. 13 illustrates an embodiment of a first process flow.

FIG. 14 illustrates an embodiment of a storage medium.

FIG. 15 illustrates an embodiment of a computing architecture.

### DETAILED DESCRIPTION

Various embodiments may be generally directed to batch placement of components, such as, for example, passive components, onto a substrate. For example, some embodiments may comprise a template having a number of depressions, or, detents, to position a number of components for placement on a substrate. During an electronic device assembly process, the components can be placed onto the template and the template manipulated (e.g., vibrated, spun, or the like) to cause the components to align in the detents. The component can be moved from the template to the substrate in a batch operation (e.g., via a vacuum picker, or the like) as opposed to individually picking and placing the components.

In some examples, the components can be aligned magnetically. More specifically, in some embodiments, the component can be placed on the template and the template passed through a magnetic field to align the components in a particular direction based on the magnetic field.

In various embodiments, a batch component placement template can include a number of primary detects while each primary detect can include a secondary detent. During operation, the components can be placed on the template and manipulated into the primary detects and then into the secondary detents.

In various embodiments, a batch component placement template can include multiple sets of detents. For example, a template can include a first set of detents for a first component and a second set of detents for a second component smaller than the first component. During operation, the first components can be placed on the template and manipulated into the first set of detents. Subsequently, the second components can be placed on the template and manipulated into the second set of detents. Both components can be aligned (e.g., magnetically, using vibrations, or the like) and then placed onto the substrate in a batch placement process (e.g., via a vacuum picker, or the like).

Various embodiments may comprise one or more elements. An element may comprise any structure arranged to perform certain operations. Each element may be implemented as hardware, software, or any combination thereof, as desired for a given set of design parameters or performance constraints. Although an embodiment may be described with a limited number of elements in a certain topology by way of example, the embodiment may include more or less elements in alternate topologies as desired for a given implementation. It is worthy to note that any reference to “one embodiment” or “an embodiment” means that a particular feature, structure, or characteristic described in connection with the embodiment is included in at least one embodiment. The appearances of the phrases “in one embodiment,” “in some embodiments,” and “in various embodiments” in various places in the specification are not necessarily all referring to the same embodiment.

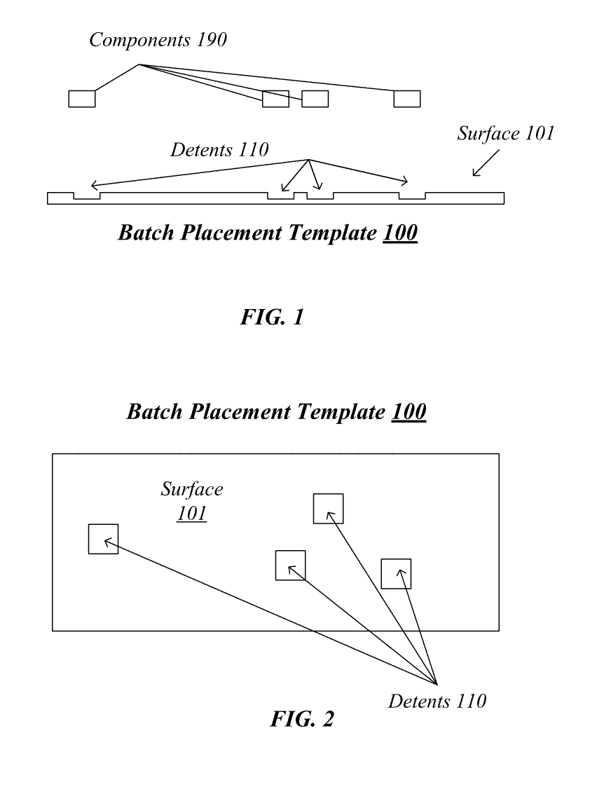

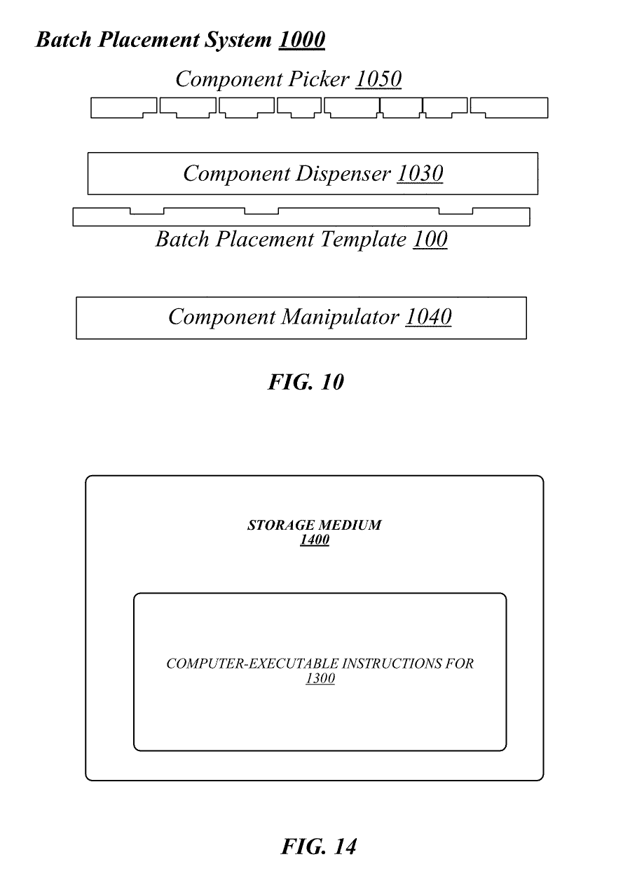

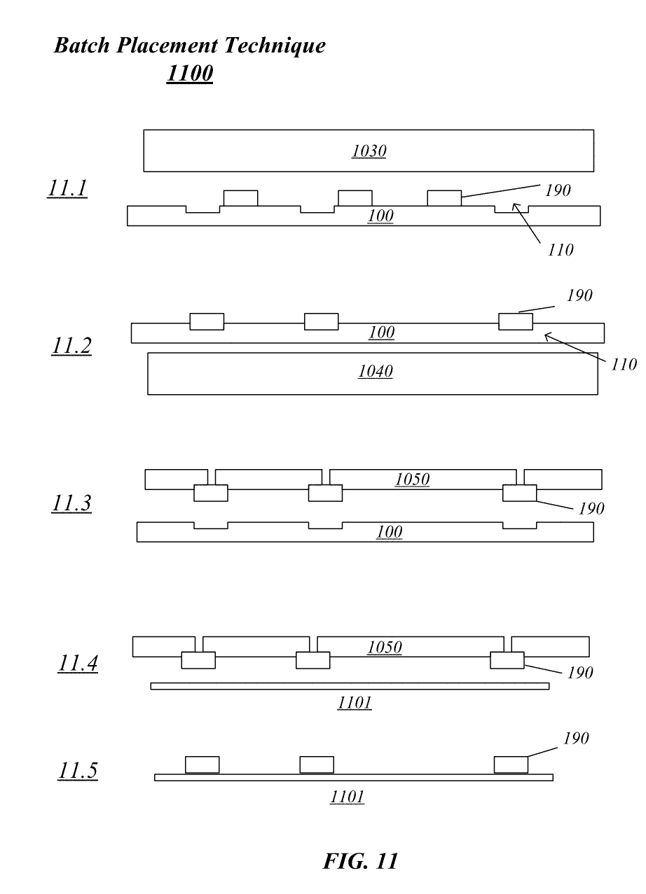

FIGS. 1 and 2 illustrate a cut-away side view and a top view, respectively, of a batch placement template 100, arranged according to embodiments of the present disclosure. In general, the batch placement template 100 can be used in a batch placement technique (e.g., refer to FIGS. 10 and 11) to position multiple components 190 to be placed on a substrate. The components 190 can be any of a variety of components of an electronic device to be mounted on a substrate (e.g., printed circuit board, or the like). For example, the components 190 can be passive components (e.g., resistors, capacitors, inductors, transformers, or the like). In some examples, the components 190 can be active components (e.g., switches, gates, processors, memory modules, or the like). Examples are not limited in this context. For convenience in discussing some example embodiments, the components 190 are referred to as capacitors. However, examples are not limited in this respect.

The batch placement template 100 can be formed from any of a variety of materials, such as, for example, metal, plastic, composites, or the like. For example, the batch placement template can be aluminum, an aluminum alloy, steel, a steel alloy, a polymer based plastic, or the like. The batch placement template can be manufactured via any of a variety of manufacturing processes, such as, for example, laser cutting, punching, 3D printing, wire mesh stacks, electrical discharge machining, or the like.

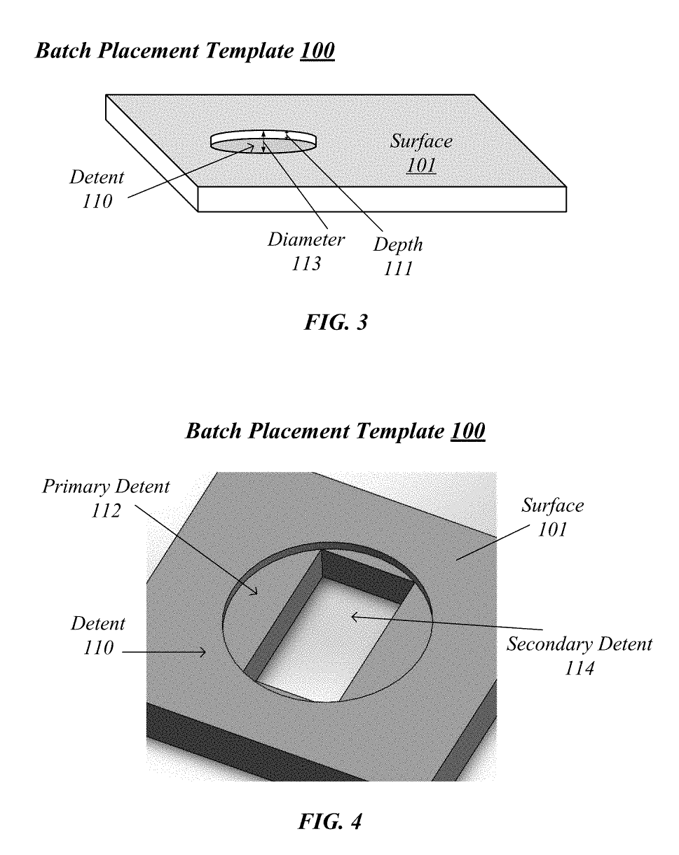

Turning more particularly to FIG. 1, as depicted, the batch placement template 100 can be a planar surface with a number of detents 110 (e.g., depressions, cavities, indentations, or the like) arranged on the surface 101 of the batch placement template 100. In general, the detents 110 can have a size and/or shape corresponding to the components 190. For example, the detents 110 can have a size and shape arranged to allow a components 190 to be manipulated into a detent 110. Furthermore, the detents 110 can have a size and shape arranged to retain the component 190 in the detent 110 once the component 190 is manipulated into the detent 110. Examples of detents 110 are given below with respect to FIGS. 3, 4, and 5A.

However, in some examples, the detent 110 can be a depression or cavity in the surface 101 of the batch placement template 100. The depth of the detents 110 into the surface 101 can be less than a height of the component 190 to be manipulated into the detents 110. Furthermore, the size of the detents 110 in the surface 101 can be larger than the size of the components 190. Accordingly, during operation, the components 190 can be manipulated to fall into the detents 110, however, the components 190 will stick out of the detents (e.g., refer to FIGS. 10 and 11) to be placed on a substrate during a batch placement technique.

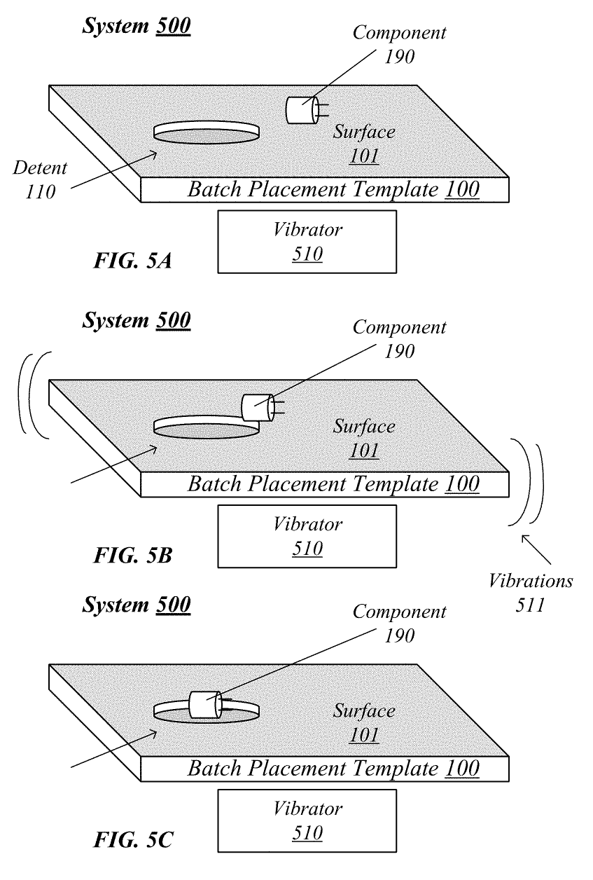

In some embodiments (e.g., refer to FIGS. 2 and 5A) the detents 110 can be square and/or rectangular shaped. In such examples, the width and length of the detents 110 can be large enough to allow the components 190 to be manipulated into the detents 110. In some embodiments (e.g., refer to FIG. 3) the detents 110 can be circular. In such examples, the diameter of the detents 110 can be large enough to allow the components 190 to be manipulated into the detents 110. In some embodiments (e.g., refer to FIG. 4) the detents 110 can have square and/or rectangular and circular features. In such examples, the diameter of the circular features of the detents 110 can be large enough to allow the components 190 to be manipulated into the detents 110 while the width and length of the rectangular features of the detents can be large enough to allow the components 190 to be manipulated into them.

It is noted, that the size and shape of the detents 110 can be small enough to position the components 190 to within a threshold or tolerance or a desired position relative to each other while still providing the components 190 can be manipulated into the detents 110. Said differently, the detents 110 can have a size and shape based on a footprint of the component 190, plus a small tolerance to allow the components to fall into the detents 110.

The detents can be arranged on the surface 101 based on desired location of the components 190 on the substrate. This is described in greater detail with respect to FIG. 2. Turning more particularly to FIG. 2, a top view of the batch placement template 100 is illustrated. As depicted, the detents 110 are positioned across the surface 101 of the batch placement template 100. Said differently, the detents 110 have a position relative to each other on the surface 101. As such, components 190 manipulated into the detents 110 can also be positioned relative to each other based on the position of the detents 110.

It is noted, that the position of the detents 110 on the surface 101 can be design specific. More particularly, the position of the detents 110 may be based on a desired position of the components 190 on a substrate (e.g., refer to FIGS. 10 and 11). Accordingly, the position of the detents 110 on the surface 101 and/or relative to each other is given for purposes of clarity only and not to be limiting.

FIG. 3 illustrates a perspective view of a portion of a batch placement template 100, according to embodiments of the present disclosure. As depicted, the batch placement template 100 includes a detent 110 in the surface 101. The detent 110 is generally circular shaped with a depth 111 and a diameter 113. The diameter 113 and depth 111 can be sized such that a component 190 can be manipulated into the detent 110 to position the component 190 in a desired location relative to other components 190.

In some embodiments, the components 190 can be manipulated across the surface 101 and into detents 110 via vibrations. In some embodiments, the components 190 can be manipulated across the surface 101 and into detents via magnetic fields. In some examples, the components 190 can be manipulated across the surface 101 and into detents 110 via rotational forces.

FIG. 4 illustrates a perspective view of a portion of a batch placement template 100, according to embodiments of the present disclosure. As depicted, the batch placement template 100 includes a detent 110 in the surface 101. The detent 110 can include a primary detent 112 and a secondary detent 114. During operation, the components 190 can be manipulated to fall into the primary detent 112 and then the secondary detent 114. More specifically, in some embodiments, the components 190 can be manipulated to fall into the circular opening of the primary detent 112. Subsequently, the components 190 can be manipulated around the axis of the primary detent 112 to fall into the secondary detent 114, thereby aligning with the orientation of the secondary detent. It may be said, that batch placement template 100 of FIG. 4 provides for an initial rough alignment of the component 190 (e.g., based on primary detent 112) and a fine alignment of the component 190 (e.g., based on secondary detent 114).

In some embodiments, the components 190 can be manipulated across the surface 101 and into detents 110 via vibrations. In some embodiments, the components 190 can be manipulated across the surface 101 and into detents via magnetic fields. In some examples, the components 190 can be manipulated across the surface 101 and into detents 110 via rotational forces. In some examples, the components 190 can be manipulated about the axis of the primary detent 112 via vibrations. In some examples, the components 190 can be manipulated about the axis of the primary detent 112 via magnetic fields. In some examples, the components 190 can be manipulated about the axis of the primary detent 112 via rotational forces.

FIGS. 5A, 5B, and 5C illustrate a system 500 to manipulate a component into a detent of a batch placement template. As depicted, the system 500 includes a batch placement template 100 and a vibrator 510, arranged according to embodiments of the present disclosure. The vibrator 510 can vibrate the batch placement template 100 or can expose the batch placement template 100 to vibrations 511. A component 190 can be placed on the surface 101 of the batch placement template 110. For example, a coin stack tube (not shown) can be implemented to dispense the components 190 onto the surface 101. It is noted, that only a single component 190 is depicted in these figures for purposes of clarity. However, it is intended that multiple components 190 be dispensed and manipulated into detents 110 (e.g., as shown in FIGS. 1-2, or the like).

For example, FIG. 5A depicts component 190 dispensed onto surface 101. FIG. 5B depicts batch placement template 100 exposed to vibrations 511, which can operate to move or manipulate component 190 towards detent 110. FIG. 5C depicts component 190 manipulated into detent 110.

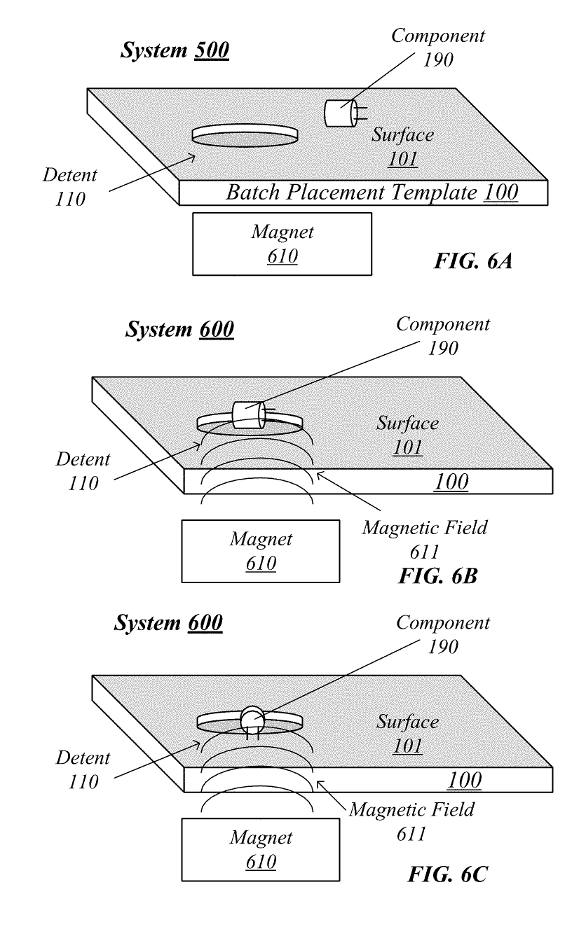

FIGS. 6A, 6B, and 6B illustrate a system 600 to manipulate a component within a detent of a batch placement template. As depicted, the system 600 includes a batch placement template 100 and a magnet 610, arranged according to embodiments of the present disclosure. The magnet 610 can emit a magnetic field 611 to manipulate and/or align the component 190. For example, in some embodiments, components 190 can include metallic materials. In some embodiments, the components 190 can be manufactured out of no-magnetic materials, but can include magnetic terminations (e.g., terminals, or the like) to eclectically couple the components 190 to a circuit. Accordingly, the components 190 can be manipulated via the magnetic field 611.

It is noted, that only a single component 190 is depicted in these figures for purposes of clarity. However, it is intended that multiple components 190 be dispensed and manipulated into detents 110 (e.g., as shown in FIGS. 1-2, or the like).

Turning more specifically to FIG. 6A. This figure depicts component 190 dispensed onto surface 101. FIG. 6B depicts batch placement template 100 exposed to magnetic field 611, which can operate to move or manipulate component 190 into detent 110. FIG. 6C depicts batch placement template 100 exposed to magnetic field 611, which can operate to move or manipulate component 190 within detent 110. In particular, as depicted, the magnetic field has operated to rotate the component 190 about the axis of the detent 110 to change positions or alignment within the detent 110.

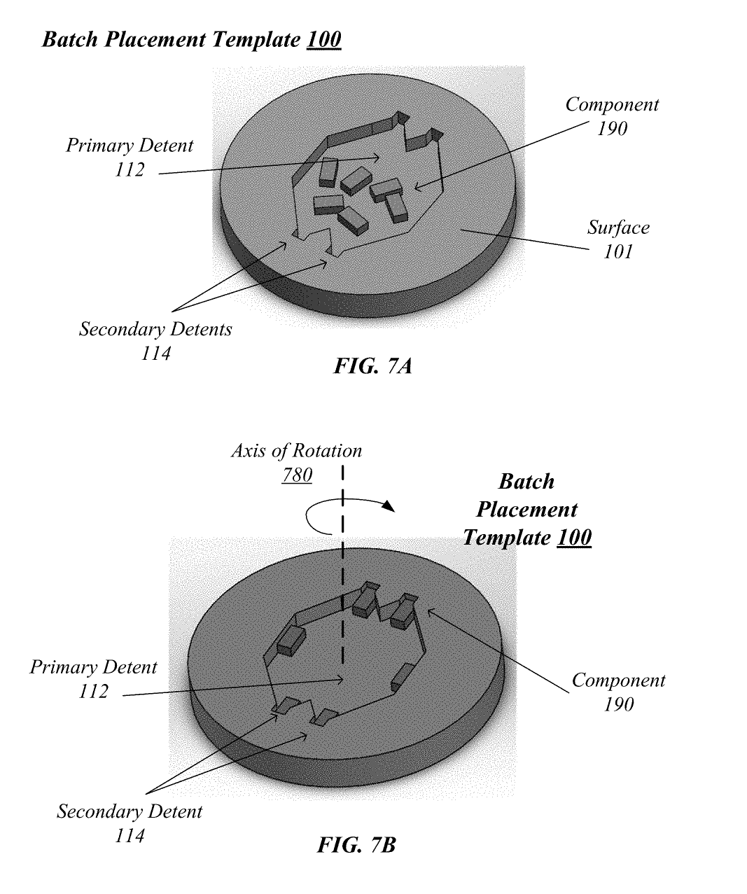

FIGS. 7A and 7B illustrate a batch placement template 100, arranged according to embodiments of the present disclosure. In particular, these figures depict a batch placement template to align component and/or manipulate components into detents using a centrifugal or a rotational force. For example, FIG. 7A depicts batch placement template 100 including a primary detent 112 and secondary detents 114. It is noted, primary detent 112 is a cavity or depression in the surface 101 while secondary detents 114 are cavities or depressions in the surface 101 arranged around the perimeter of the primary detent 112. Accordingly, during operation, components 190 can be dispensed into primary detent 112. For example, this figure depicts components 190 dispensed into primary detent 112.

Turning more specifically to FIG. 7B, the batch placement template is depicted rotating about an axis 780. For example, the batch placement template 100 can be operably coupled to a rotor (not shown) to rotate the batch placement template 100 about the axis 780. Accordingly, a centrifugal force could be applied to components 190 to manipulate components 190 towards the perimeter of the primary detent 112 and into secondary detents 114.

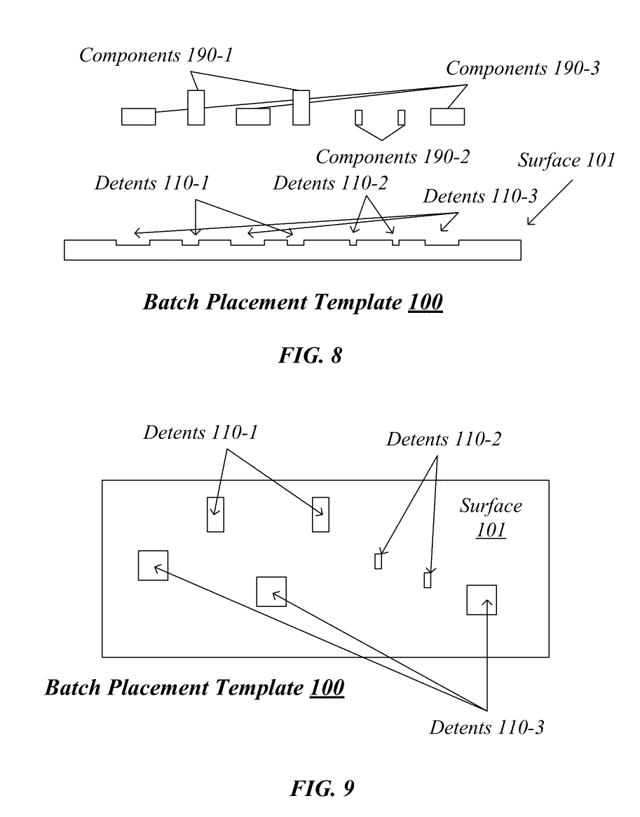

FIGS. 8 and 9 illustrate a cut-away side view and a top view, respectively, of a batch placement template 100, arranged according to embodiments of the present disclosure. In general, the batch placement template 100 can be used in a batch placement technique (e.g., refer to FIGS. 10 and 11) to position multiple components 190 to be placed on a substrate. It is noted, that the component 190 can be different components and/or can be components having different sizes, shapes, and/or footprints. For example, components 190-1, 190-2, and 190-3 are depicted. Each of the components 190-1, 190-2, and 190-3 have different size and/or footprints.

Turning more particularly to FIG. 8, as depicted, the batch placement template 100 can be a planar surface with a number of different sized detents 110 (e.g., depressions, cavities, indentations, or the like) arranged on the surface 101 of the batch placement template 100. In particular, the batch placement template 100 is depicted including detents 110-1, 110-2, and 110-3. In particular, detents 110-1, 110-2, and 110-3 can have a size and/or shape corresponding to the components 190-1, 190-2, and 190-3, respectively.

The detents 110-1, 110-2, and 110-3 can be arranged on the surface 101 based on desired location of the components 190 on the substrate. This is described in greater detail with respect to FIG. 9. Turning more particularly to FIG. 9, a top view of the batch placement template 100 is illustrated. As depicted, the detents 110-1, 110-2, and 110-3 are positioned across the surface 101 of the batch placement template 100. Said differently, the detents 110-1, 110-2, and 110-3 have a position relative to each other on the surface 101. As such, components 190-1, 190-2, and 190-3 are manipulated into the detents 110-1, 110-2, and 110-3, the components can also be positioned relative to each other based on the position of the detents.

It is noted, that the position of the detents on the surface 101 can be design specific. More particularly, the position of the detents may be based on a desired position of the components 190-1, 190-2, and 190-3 on a substrate (e.g., refer to FIGS. 10 and 11). Accordingly, the position of the detents 110 on the surface 101 and/or relative to each other is given for purposes of clarity only and not to be limiting.

In some examples, the components 190-1, 190-2, and 190-3 can be dispended onto the batch placement template from largest to smallest. For example, the components 190-1 can first be dispensed onto surface 101 and manipulate into detents 110-1. Subsequently, the components 190-2 can be dispensed onto surface 101 and manipulated into detents 110-2. Subsequently, the components 190-3 can be dispensed onto surface 101 and manipulated into detents 110-3. Accordingly, the smaller components may be prevented from being manipulated into detents meant for a larger components (e.g., components 190-3 prevented from being manipulate into detent 110-1, or the like).

FIG. 10 illustrates a batch placement system 1000, arranged according to examples of the present disclosure. The batch placement system 1000 includes a batch placement template 100, a component dispenser 1030, a component manipulator 1040, and a component picker 1050.

In general, the batch placement template 100 can be any batch placement template to align multiple component for placement in a batch process. For example, the batch placement template 100 can be any of the batch placement templates described with respect to FIGS. 1, 2, 3, 4, 7A and 7B, 8, or 9.

The component dispenser 1030 can be any of a variety of devices to dispense components 190 onto surface 101 and/or into primary detents 112. For example, the component dispenser 1030 can be a coin stack component dispensing device, or the like.

The component manipulator 1040 can be any of a variety of device to manipulate the components 190 into detents 110. For example, the component manipulator 1040 can be a vibrator, a magnet, a rotor, or the like.

The component picker 1050 can be any of a variety of devices to pick components 190 from detents 110 and place components 190 onto a substrate in a batch process. For example, the component picker 1050 can be a vacuum picking device, an electro static picking device or the like. In some examples, the component picker 1050 can be arranged to pick components 190 of different sizes (e.g., components 190-1, 190-2, 190-3, or the like). For example, the component picker 1050 can have telescoping heads to accommodate different sized components in a single process. It is noted, that the system 1000 can be robotic and/or automated to implement an electronic device assembly process.

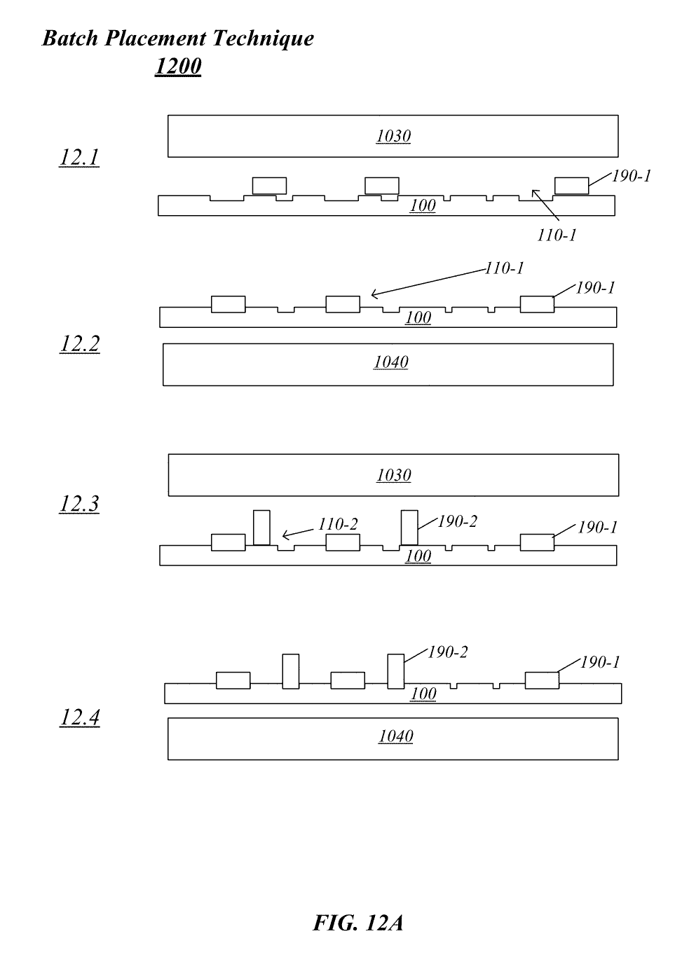

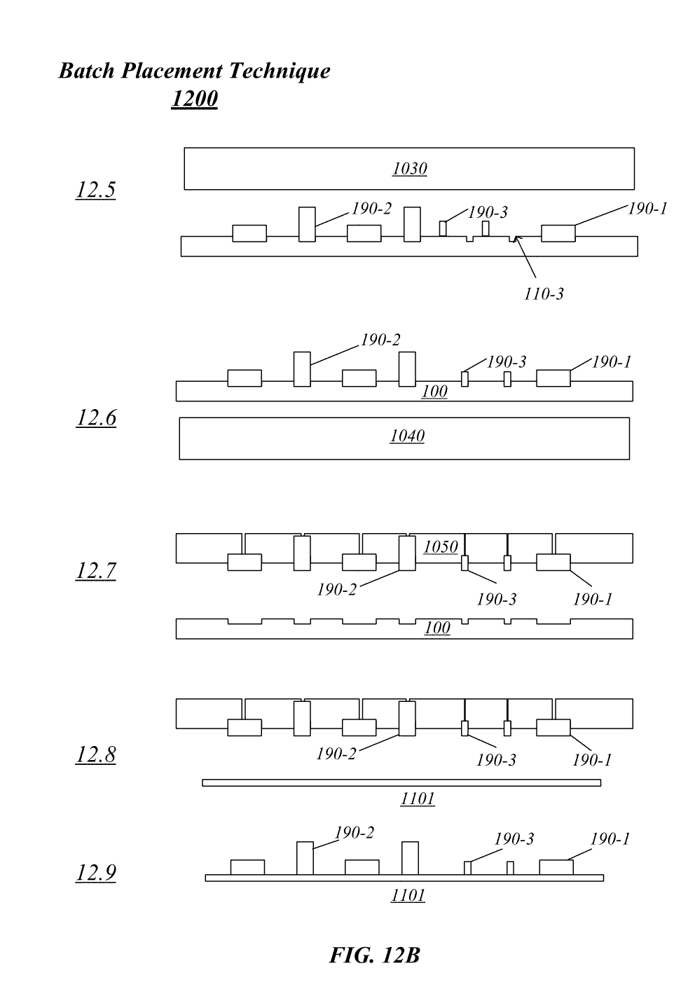

FIGS. 11 and 12A and 12B illustrate techniques to place multiple components onto a substrate in a batch process, according to embodiments of the present disclosure. In general, the technique illustrates placing components using a batch placement template, such as, for example, the batch placement templates of FIGS. 1, 2, 3, 4, 7A and 7B, 8, or 9 and a batch placement system, such as, for example, the batch placement system of FIG. 10.

Turning more particularly to FIG. 11, the technique 1100 is depicted. Technique 1100 can begin at block 11.1. At block 11.1 component dispenser 1030 can dispense components 190 onto a surface 101 of batch placement template 100. Continuing to block 11.2, component manipulator 1040 can manipulate (e.g., via vibrations, rotations, magnetic fields, or the like) components 190 into detents 110 of batch placement template 100. Continuing to block 11.3, component picker 1050 can pick (e.g., via vacuum, static, or the like) component 190 from detents 110. Continuing to block 11.4, component picker 1050 can move components 190 over a substrate 1101 upon which components are to be placed. Said differently, component picker 1050 can be move component 190 to a substrate as part of an electronic device assembly and/or manufacturing process. Continuing to block 11.5, component 190 can be secured and/or attached to substrate (e.g., via bonding, soldering, mechanical attachment, or the like) in positions corresponding to the position of the detents 110 of the batch placement template 100.

Turning more particularly to FIGS. 12A and 12B, the technique 1200 is depicted. Technique 1200 can begin at block 12.1. At block 12.1 component dispenser 1030 can dispense components 190-1 onto a surface 101 of batch placement template 100. As depicted, the components 190-1 are sized such that they cannot be manipulated into detents 110-2 and 110-3. Continuing to block 12.2, component manipulator 1040 can manipulate (e.g., via vibrations, rotations, magnetic fields, or the like) components 190-1 into detents 110-1 of batch placement template 100. Continuing to block 12.3, component dispenser 1030 can dispense components 190-2 onto a surface 101 of batch placement template 100. As depicted, the components 190-2 are sized such that they cannot be manipulated into detents 110-3. Furthermore, as components 190-1 are already manipulated into detents 110-1, components 190-2 cannot be manipulated into detents 110-1 either. Continuing to block 12.4, component manipulator 1040 can manipulate (e.g., via vibrations, rotations, magnetic fields, or the like) components 190-2 into detents 110-2 of batch placement template 100. Continuing to block 12.5, component dispenser 1030 can dispense components 190-3 onto a surface 101 of batch placement template 100. As depicted, the components 190-3 are sized such that they can only be manipulated into detents 110-3. Furthermore, as components 190-1 and 190-2 are already manipulated into detents 110-1 and 110-2, respectively, components 190-3 cannot be manipulated into detents 110-1 or 110-2. Continuing to block 12.6, component manipulator 1040 can manipulate (e.g., via vibrations, rotations, magnetic fields, or the like) components 190-3 into detents 110-3 of batch placement template 100.

Continuing to block 12.7, component picker 1050 can pick (e.g., via vacuum, static, or the like) components 190-1, 190-2, and 190-3 from detents 110-1, 110-2, and 110-3. Continuing to block 12.8, component picker 1050 can move components 190-1, 190-2, and 190-3 over a substrate 1101 upon which the components are to be placed. Said differently, component picker 1050 can be move components 190-1, 190-2, and 190-3 to a substrate as part of an electronic device assembly and/or manufacturing process. Continuing to block 12.9, components 190-1, 190-2, and 190-3 can be secured and/or attached to substrate 1101 (e.g., via bonding, soldering, mechanical attachment, or the like) in positions corresponding to the position of the detents 111-1, 110-2, and 110-3 of the batch placement template 100.

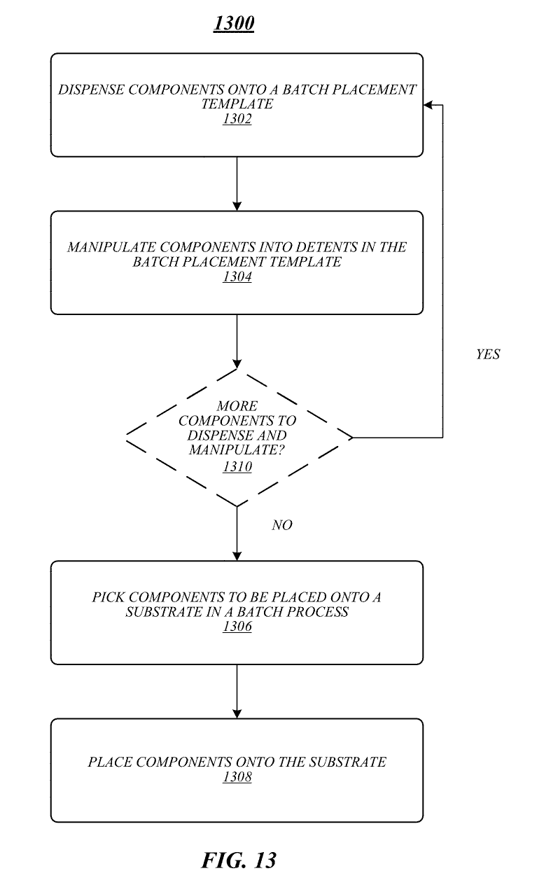

FIG. 13 illustrates an example of a process flow 1300 that may be representative of the implementation of one or more of the disclosed techniques according to some embodiments. For example, process flow 1300 may be representative of one or both of the batch placement techniques of FIGS. 11 or 12A and 12B. As shown in this figure, components can be dispensed onto a surface of a batch placement template at 1302. For example, components 190 can be dispensed (e.g., via dispenser 1030, or the like) onto surface 101 of batch placement template. At 1304, the components can be manipulated (e.g., via manipulator 1040, or the like) into detents in the surface of the batch placement template. For example, components 190 can be manipulated into detents 110 of the batch placement template 100. At 1306 the components can be picked in a pick and place process. For example, components 190 can be picked (e.g., via picker 1050, or the like) from detents 110 in the batch placement template 100. At block 1308 the components can be placed on a substrate. For example, components 190 can be placed (e.g., via picker 1050, or the like) on substrate 1101.

Additionally, process flow 1300 can include an optional decision block 1310 between blocks 1304 and 1306. At decision block 1310, process flow may branch and return to block 1302 based on a determination that more components are to be placed onto batch placement template and manipulated into detents. Alternatively, process flow may continue from block 1304 to block 1306 as described above.

FIG. 14 illustrates an embodiment of a storage medium 1400. Storage medium 1400 may comprise any computer-readable storage medium or machine-readable storage medium, such as an optical, magnetic or semiconductor storage medium. In various embodiments, storage medium 1400 may comprise an article of manufacture. In some embodiments, storage medium 1400 may comprise a non-transitory storage medium. In some embodiments, storage medium 1400 may store computer-executable instructions, such as computer-executable instructions to implement one or more of technique 1100 of FIG. 11, technique 1200 of FIGS. 12A and 12B, or process flow 1300 of FIG. 13. Examples of a computer-readable storage medium or machine-readable storage medium may include any tangible media capable of storing electronic data, including volatile memory or non-volatile memory, removable or non-removable memory, erasable or non-erasable memory, writeable or re-writeable memory, and so forth. Examples of computer-executable instructions may include any suitable type of code, such as source code, compiled code, interpreted code, executable code, static code, dynamic code, object-oriented code, visual code, and the like. The embodiments are not limited in this context.

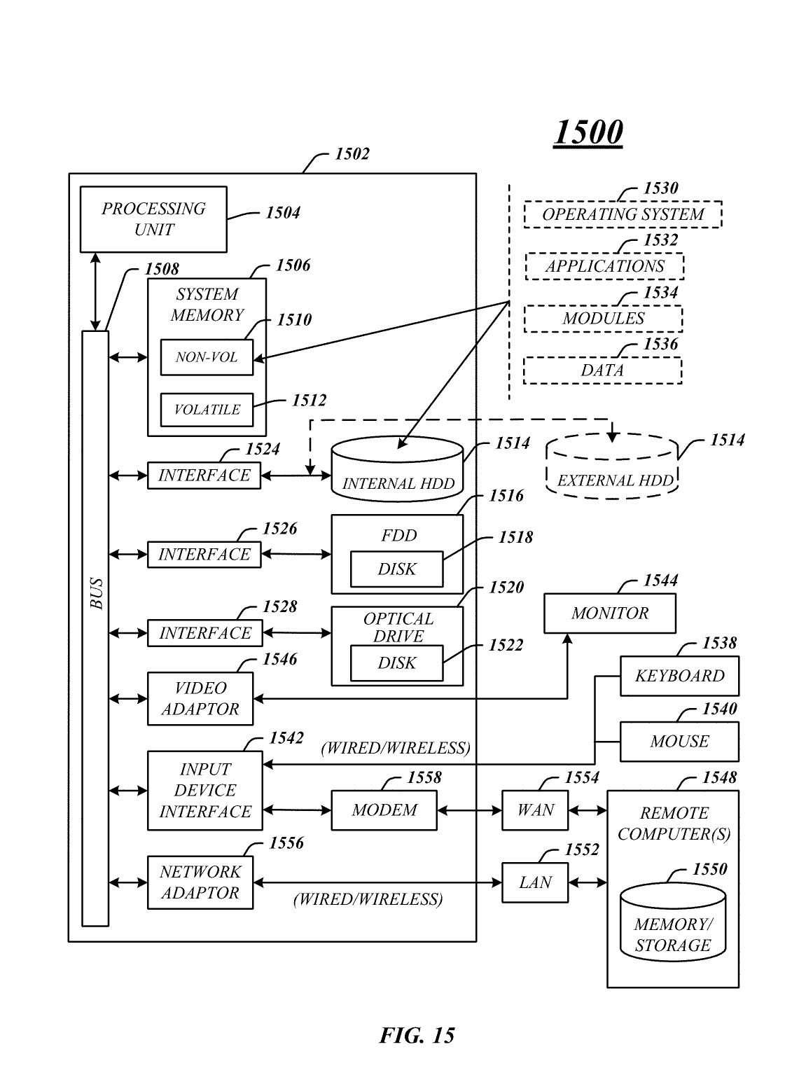

FIG. 15 illustrates an embodiment of an exemplary computing architecture 1500 that may be suitable for implementing various embodiments as previously described. In various embodiments, the computing architecture 1500 may comprise or be implemented as part of an electronic device. In some embodiments, the computing architecture 1500 may be representative of a computing device that comprises a structure featuring an electronic assembly constructed to one or more of the disclosed techniques, such as one or more of the technique 1100 of FIG. 11, technique 1200 of FIGS. 12A and 12B, or process flow 1300 of FIG. 13. The embodiments are not limited in this context.

As used in this application, the terms “system” and “component” and “module” are intended to refer to a computer-related entity, either hardware, a combination of hardware and software, software, or software in execution, examples of which are provided by the exemplary computing architecture 1500. For example, a component can be, but is not limited to being, a process running on a processor, a processor, a hard disk drive, multiple storage drives (of optical and/or magnetic storage medium), an object, an executable, a thread of execution, a program, and/or a computer. By way of illustration, both an application running on a server and the server can be a component. One or more components can reside within a process and/or thread of execution, and a component can be localized on one computer and/or distributed between two or more computers. Further, components may be communicatively coupled to each other by various types of communications media to coordinate operations. The coordination may involve the uni-directional or bi-directional exchange of information. For instance, the components may communicate information in the form of signals communicated over the communications media. The information can be implemented as signals allocated to various signal lines. In such allocations, each message is a signal. Further embodiments, however, may alternatively employ data messages. Such data messages may be sent across various connections. Exemplary connections include parallel interfaces, serial interfaces, and bus interfaces.

The computing architecture 1500 includes various common computing elements, such as one or more processors, multi-core processors, co-processors, memory units, chipsets, controllers, peripherals, interfaces, oscillators, timing devices, video cards, audio cards, multimedia input/output (I/O) components, power supplies, and so forth. The embodiments, however, are not limited to implementation by the computing architecture 1500.

As shown in FIG. 15, according to computing architecture 1500, a computer 1502 comprises a processing unit 1504, a system memory 1506 and a system bus 1508. In some embodiments, computer 1502 may comprise a server. In some embodiments, computer 1502 may comprise a client. The processing unit 1504 can be any of various commercially available processors, including without limitation an AMD® Athlon®, Duron® and Opteron® processors; ARM® application, embedded and secure processors; IBM® and Motorola® DragonBall® and PowerPC® processors; IBM and Sony® Cell processors; Intel® Celeron®, Core (2) Duo®, Itanium®, Pentium®, Xeon®, and XScale® processors; and similar processors. Dual microprocessors, multi-core processors, and other multi-processor architectures may also be employed as the processing unit 1504.

The system bus 1508 provides an interface for system components including, but not limited to, the system memory 1506 to the processing unit 1504. The system bus 1508 can be any of several types of bus structure that may further interconnect to a memory bus (with or without a memory controller), a peripheral bus, and a local bus using any of a variety of commercially available bus architectures. Interface adapters may connect to the system bus 1508 via a slot architecture. Example slot architectures may include without limitation Accelerated Graphics Port (AGP), Card Bus, (Extended) Industry Standard Architecture ((E)ISA), Micro Channel Architecture (MCA), NuBus, Peripheral Component Interconnect (Extended) (PCI(X)), PCI Express, Personal Computer Memory Card International Association (PCMCIA), and the like.

The system memory 1506 may include various types of computer-readable storage media in the form of one or more higher speed memory units, such as read-only memory (ROM), random-access memory (RAM), dynamic RAM (DRAM), Double-Data-Rate DRAM (DDRAM), synchronous DRAM (SDRAM), static RAM (SRAM), programmable ROM (PROM), erasable programmable ROM (EPROM), electrically erasable programmable ROM (EEPROM), flash memory, polymer memory such as ferroelectric polymer memory, ovonic memory, phase change or ferroelectric memory, silicon-oxide-nitride-oxide-silicon (SONOS) memory, magnetic or optical cards, an array of devices such as Redundant Array of Independent Disks (RAID) drives, solid state memory devices (e.g., USB memory, solid state drives (SSD) and any other type of storage media suitable for storing information. In the illustrated embodiment shown in FIG. 15, the system memory 1506 can include non-volatile memory 1510 and/or volatile memory 1512. A basic input/output system (BIOS) can be stored in the non-volatile memory 1510.

The computer 1502 may include various types of computer-readable storage media in the form of one or more lower speed memory units, including an internal (or external) hard disk drive (HDD) 1514, a magnetic floppy disk drive (FDD) 1516 to read from or write to a removable magnetic disk 1518, and an optical disk drive 1520 to read from or write to a removable optical disk 1522 (e.g., a CD-ROM or DVD). The HDD 1514, FDD 1516 and optical disk drive 1520 can be connected to the system bus 1508 by a HDD interface 1524, an FDD interface 1526 and an optical drive interface 1528, respectively. The HDD interface 1524 for external drive implementations can include at least one or both of Universal Serial Bus (USB) and IEEE 1394 interface technologies.

The drives and associated computer-readable media provide volatile and/or nonvolatile storage of data, data structures, computer-executable instructions, and so forth. For example, a number of program modules can be stored in the drives and memory units 1510, 1512, including an operating system 1530, one or more application programs 1532, other program modules 1534, and program data 1536.

A user can enter commands and information into the computer 1502 through one or more wire/wireless input devices, for example, a keyboard 1538 and a pointing device, such as a mouse 1540. Other input devices may include microphones, infra-red (IR) remote controls, radio-frequency (RF) remote controls, game pads, stylus pens, card readers, dongles, finger print readers, gloves, graphics tablets, joysticks, keyboards, retina readers, touch screens (e.g., capacitive, resistive, etc.), trackballs, trackpads, sensors, styluses, and the like. These and other input devices are often connected to the processing unit 1504 through an input device interface 1542 that is coupled to the system bus 1508, but can be connected by other interfaces such as a parallel port, IEEE 1394 serial port, a game port, a USB port, an IR interface, and so forth.

A monitor 1544 or other type of display device is also connected to the system bus 1508 via an interface, such as a video adaptor 1546. The monitor 1544 may be internal or external to the computer 1502. In addition to the monitor 1544, a computer typically includes other peripheral output devices, such as speakers, printers, and so forth.

The computer 1502 may operate in a networked environment using logical connections via wire and/or wireless communications to one or more remote computers, such as a remote computer 1548. The remote computer 1548 can be a workstation, a server computer, a router, a personal computer, portable computer, microprocessor-based entertainment appliance, a peer device or other common network node, and typically includes many or all of the elements described relative to the computer 1502, although, for purposes of brevity, only a memory/storage device 1550 is illustrated. The logical connections depicted include wire/wireless connectivity to a local area network (LAN) 1552 and/or larger networks, for example, a wide area network (WAN) 1554. Such LAN and WAN networking environments are commonplace in offices and companies, and facilitate enterprise-wide computer networks, such as intranets, all of which may connect to a global communications network, for example, the Internet.

When used in a LAN networking environment, the computer 1502 is connected to the LAN 1552 through a wire and/or wireless communication network interface or adaptor 1556. The adaptor 1556 can facilitate wire and/or wireless communications to the LAN 1552, which may also include a wireless access point disposed thereon for communicating with the wireless functionality of the adaptor 1556.

When used in a WAN networking environment, the computer 1502 can include a modem 1558, or is connected to a communications server on the WAN 1554, or has other means for establishing communications over the WAN 1554, such as by way of the Internet. The modem 1558, which can be internal or external and a wire and/or wireless device, connects to the system bus 1508 via the input device interface 1542. In a networked environment, program modules depicted relative to the computer 1502, or portions thereof, can be stored in the remote memory/storage device 1550. It will be appreciated that the network connections shown are exemplary and other means of establishing a communications link between the computers can be used.

The computer 1502 is operable to communicate with wire and wireless devices or entities using the IEEE 802 family of standards, such as wireless devices operatively disposed in wireless communication (e.g., IEEE 802.16 over-the-air modulation techniques). This includes at least Wi-Fi (or Wireless Fidelity), WiMax, and Bluetooth™ wireless technologies, among others. Thus, the communication can be a predefined structure as with a conventional network or simply an ad hoc communication between at least two devices. Wi-Fi networks use radio technologies called IEEE 802.11x (a, b, g, n, etc.) to provide secure, reliable, fast wireless connectivity. A Wi-Fi network can be used to connect computers to each other, to the Internet, and to wire networks (which use IEEE 802.3-related media and functions).

Various embodiments may be implemented using hardware elements, software elements, or a combination of both. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores” may be stored on a tangible, machine readable medium and supplied to various customers or manufacturing facilities to load into the fabrication machines that actually make the logic or processor. Some embodiments may be implemented, for example, using a machine-readable medium or article which may store an instruction or a set of instructions that, if executed by a machine, may cause the machine to perform a method and/or operations in accordance with the embodiments. Such a machine may include, for example, any suitable processing platform, computing platform, computing device, processing device, computing system, processing system, computer, processor, or the like, and may be implemented using any suitable combination of hardware and/or software. The machine-readable medium or article may include, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions may include any suitable type of code, such as source code, compiled code, interpreted code, executable code, static code, dynamic code, encrypted code, and the like, implemented using any suitable high-level, low-level, object-oriented, visual, compiled and/or interpreted programming language.

Numerous specific details have been set forth herein to provide a thorough understanding of the embodiments. It will be understood by those skilled in the art, however, that the embodiments may be practiced without these specific details. In other instances, well-known operations, components, and circuits have not been described in detail so as not to obscure the embodiments. It can be appreciated that the specific structural and functional details disclosed herein may be representative and do not necessarily limit the scope of the embodiments.

Some embodiments may be described using the expression “coupled” and “connected” along with their derivatives. These terms are not intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still co-operate or interact with each other.

Unless specifically stated otherwise, it may be appreciated that terms such as “processing,” “computing,” “calculating,” “determining,” or the like, refer to the action and/or processes of a computer or computing system, or similar electronic computing device, that manipulates and/or transforms data represented as physical quantities (e.g., electronic) within the computing system's registers and/or memories into other data similarly represented as physical quantities within the computing system's memories, registers or other such information storage, transmission or display devices. The embodiments are not limited in this context.

It should be noted that the methods described herein do not have to be executed in the order described, or in any particular order. Moreover, various activities described with respect to the methods identified herein can be executed in serial or parallel fashion.

Although specific embodiments have been illustrated and described herein, it should be appreciated that any arrangement calculated to achieve the same purpose may be substituted for the specific embodiments shown. This disclosure is intended to cover any and all adaptations or variations of various embodiments. It is to be understood that the above description has been made in an illustrative fashion, and not a restrictive one. Combinations of the above embodiments, and other embodiments not specifically described herein will be apparent to those of skill in the art upon reviewing the above description. Thus, the scope of various embodiments includes any other applications in which the above compositions, structures, and methods are used.

It is emphasized that the Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate preferred embodiment. In the appended claims, the terms “including” and “in which” are used as the plain-English equivalents of the respective terms “comprising” and “wherein,” respectively. Moreover, the terms “first,” “second,” and “third,” etc. are used merely as labels, and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

Example 1. A system to place a plurality of components on a substrate in a batch, comprising: a batch placement template comprising a surface and a plurality of detents in the surface; a component dispenser to dispense a plurality of components onto the surface; and a component manipulator to manipulate the plurality of components into the plurality of detents.

Example 2. The system of example 1, comprising a component picker to pick the plurality of component from the plurality of detents in a batch.

Example 3. The system of example 2, the component picker to place the plurality of component onto a substrate.

Example 4. The system of example 2, wherein the detents are arranged, relative to each other, on the surface of the batch placement template based on a targeted position of the plurality of components, relative to each other, on a substrate.

Example 5. The system of example 1, the component manipulator to expose the surface of the batch placement template to vibrations to manipulate the plurality of components across the surface.

Example 6. The system of example 1, the component manipulator to expose the surface of the batch placement template to a magnetic field to manipulate the plurality of components across the surface.

Example 7. The system of example 1, the component manipulator to rotate the surface about a central axis to manipulate the plurality of components across the surface.

Example 8. The system of example 1, the component manipulator to align the plurality of components within the detents.

Example 9. The system of example 8, the component manipulator to expose the plurality of components to a magnetic field to align the plurality of components.

Example 10. The system of any one of examples 1 to 9, each of the detents of the plurality of detents comprising a primary detent and a secondary detent, the component manipulator to: manipulate the plurality of component into the primary detents; and manipulate the plurality of components into the secondary detents.

Example 11. The system of example 10, the component manipulator to expose the surface of the batch placement template to at least one of vibrations, a magnetic field, or rotational forces to manipulate the plurality of components across the surface into the primary detents.

Example 12. The system of example 11, the component manipulator to expose the surface of the batch placement template to at least one of vibrations, a magnetic field, or rotational forces to manipulate the plurality of components within the primary detent and into the secondary detents.

Example 13. The system of example 12, wherein the primary detent is cylindrical shaped and the secondary detents are prism shaped.

Example 14. An apparatus comprising: a prism having an upper surface; a plurality of detents in the upper surface, each of the plurality of detents comprising an area equal to or larger than an area of a component to be manipulated into the detents, wherein each of the plurality detents are arranged, relative to each other, on the upper surface based on a targeted position of a plurality of components, relative to each other, to be placed on a substrate.

Example 15. The apparatus of example 14, the plurality of detents comprising a depth that is less than a height of the plurality of components.

Example 16. The apparatus of example 14, each of the detents of the plurality of detents comprising a primary detent and a secondary detent, each of the secondary detents a detent within a corresponding primary detent.

Example 17. The apparatus of example 16, wherein the primary detent is cylindrical shaped and the secondary detents are prism shaped.

Example 18. A method to place components on a substrate, the method comprising: dispensing a plurality of components onto a surface of a batch placement template, the batch placement template comprising the surface and a plurality of detents in the surface, each of the plurality of detents having an area equal to or greater than an area of each of the plurality of components; manipulating the plurality of component into the plurality of detents; and picking the plurality of components from the detents in a batch process.

Example 19. The method of example 18, comprising placing the plurality of components onto a surface of a substrate in a batch process.

Example 20. The method of example 18, wherein the detents are arranged, relative to each other, on the surface of the batch placement template based on a targeted position of the plurality of components, relative to each other, on a substrate.

Example 21. The method of example 18, manipulating the plurality of components into the plurality of detents comprising exposing the surface of the batch placement template to vibrations to manipulate the plurality of components across the surface.

Example 22. The method of example 18, manipulating the plurality of components into the plurality of detents comprising exposing the surface of the batch placement template to a magnetic field to manipulate the plurality of components across the surface.

Example 23. The method of example 18, manipulating the plurality of components into the plurality of detents comprising rotating the surface about a central axis to manipulate the plurality of components across the surface.

Example 24. The method of example 18, comprising aligning the plurality of components within the detents.

Example 25. The method of example 24, comprising exposing the plurality of components to a magnetic field to align the plurality of components.

Example 26. The method of example 18, the plurality of components a first set of components and the plurality of detents a first set of detents, the method comprising: dispensing a plurality of components of a second set of components onto the surface of the batch placement template, each component of the second set of components having an area smaller than the area of the plurality of components of the first set of components; and manipulating the plurality of component of the second set of components into a plurality of detents of a second set of detents in the surface of the batch placement template, each of the plurality of detents of the second set of detents having an area equal to or greater than an area of each of the plurality of components of the second set of components.

Example 27. The method of example 26, picking the plurality of components from the detents in a batch process comprising picking the plurality of components of the first set of components and the second set of components in a batch process.

Example 28. The method of any one of examples 18 to 27, each of the detents of the plurality of detents comprising a primary detent and a secondary detent, the method comprising: manipulating the plurality of component into the primary detents; and manipulating the plurality of components into the secondary detents.

Example 29. The method of example 28, manipulating the plurality of components into the primary detents comprising exposing the surface of the batch placement template to at least one of vibrations, a magnetic field, or rotational forces to manipulate the plurality of components across the surface.

Example 30. The method of example 29, manipulating the plurality of components into the secondary detents comprising exposing the surface of the batch placement template to at least one of vibrations, a magnetic field, or rotational forces to manipulate the plurality of components within the primary detent.

Example 31. The method of example 12, wherein the primary detent is cylindrical shaped and the secondary detents are prism shaped.

What is claimed is:

1. A system to place a plurality of components on a substrate in a batch, comprising:
a batch placement template comprising a surface and a plurality of detents in the surface;
a component dispenser to dispense a plurality of components onto the surface; and
a component manipulator to manipulate the plurality of components into the plurality of detents.

2. The system of claim 1, comprising a component picker to pick the plurality of component from the plurality of detents in a batch.

3. The system of claim 2, the component picker to place the plurality of component onto a substrate.

4. The system of claim 2, wherein the detents are arranged, relative to each other, on the surface of the batch placement template based on a targeted position of the plurality of components, relative to each other, on a substrate.

5. The system of claim 1, the component manipulator to expose the surface of the batch placement template to vibrations, a magnetic field, or rotational force to manipulate the plurality of components across the surface.

6. The system of claim 1, the component manipulator to align the plurality of components within the detents.

7. The system of claim 6, the component manipulator to expose the plurality of components to a magnetic field to align the plurality of components.

8. The system of claim 1, each of the detents of the plurality of detents comprising a primary detent and a secondary detent, the component manipulator to:
manipulate the plurality of component into the primary detents; and
manipulate the plurality of components into the secondary detents.

9. The system of claim 8, the component manipulator to expose the surface of the batch placement template to at least one of vibrations, a magnetic field, or rotational forces to manipulate the plurality of components across the surface into the primary detents.

10. The system of claim 9, the component manipulator to expose the surface of the batch placement template to at least one of vibrations, a magnetic field, or rotational forces to manipulate the plurality of components within the primary detent and into the secondary detents.

11. The system of claim 10, wherein the primary detent is cylindrical shaped and the secondary detents are prism shaped.

12. An apparatus comprising:
a prism having an upper surface;
a plurality of detents in the upper surface, each of the plurality of detents comprising an area equal to or larger than an area of a component to be manipulated into the detents, wherein each of the plurality detents are arranged, relative to each other, on the upper surface based on a targeted position of a plurality of components, relative to each other, to be placed on a substrate.

13. The apparatus of claim 12, the plurality of detents comprising a depth that is less than a height of the plurality of components.

14. The apparatus of claim 12, each of the detents of the plurality of detents comprising a primary detent and a secondary detent, each of the secondary detents a detent within a corresponding primary detent.

15. The apparatus of claim 14, wherein the primary detent is cylindrical shaped and the secondary detents are prism shaped.

16. A method to place components on a substrate, the method comprising:
dispensing a plurality of components onto a surface of a batch placement template, the batch placement template comprising the surface and a plurality of detents in the surface, each of the plurality of detents having an area equal to or greater than an area of each of the plurality of components;
manipulating the plurality of component into the plurality of detents; and
picking the plurality of components from the detents in a batch process.

17. The method of claim 16, comprising placing the plurality of components onto a surface of a substrate in a batch process.

18. The method of claim 16, wherein the detents are arranged, relative to each other, on the surface of the batch placement template based on a targeted position of the plurality of components, relative to each other, on a substrate.

19. The method of claim 16, manipulating the plurality of components into the plurality of detents comprising exposing the surface of the batch placement template to vibrations, a magnetic filed, or rotational forces to manipulate the plurality of components across the surface.

20. The method of claim 16, comprising aligning the plurality of components within the detents.

21. The method of claim 20, comprising exposing the plurality of components to a magnetic field to align the plurality of components.

22. The method of claim 16, the plurality of components a first set of components and the plurality of detents a first set of detents, the method comprising:
dispensing a plurality of components of a second set of components onto the surface of the batch placement template, each component of the second set of components having an area smaller than the area of the plurality of components of the first set of components; and
manipulating the plurality of component of the second set of components into a plurality of detents of a second set of detents in the surface of the batch placement template, each of the plurality of detents of the second set of detents having an area equal to or greater than an area of each of the plurality of components of the second set of components.

23. The method of claim 22, picking the plurality of components from the detents in a batch process comprising picking the plurality of components of the first set of components and the second set of components in a batch process.

24. The method of any one of claims 16, each of the detents of the plurality of detents comprising a primary detent and a secondary detent, the method comprising:
manipulating the plurality of component into the primary detents; and
manipulating the plurality of components into the secondary detents.

25. The method of claim 24, manipulating the plurality of components into the primary detents comprising exposing the surface of the batch placement template to at least one of vibrations, a magnetic field, or rotational forces to manipulate the plurality of components across the surface and manipulating the plurality of components into the secondary detents comprising exposing the surface of the batch placement template to at least one of vibrations, a magnetic field, or rotational forces to manipulate the plurality of components within the primary detent.
